(19) United States
(12) Patent Application Publication
(10) Pub. No.: US 2023/0323532 A1
(43) Pub. Date: Oct. 12, 2023

(54) RIB COVER FOR MULTI-STATION PROCESSING MODULES

(71) Applicant: Lam Research Corporation, Fremont, CA (US)

(72) Inventors: Keith Joseph Martin, Tualatin, OR (US); Todd Schroeder, Sherwood, OR (US); Kevin M. McLaughlin, Sherwood, OR (US); Jiuyuan Nie, Tualatin, OR (US); Jialing Yang, Sherwood, OR (US); Chee Whye Woo, Lake Oswego, OR (US)

(21) Appl. No.: 18/024,045

(22) PCT Filed: Aug. 30, 2021
(86) PCT No.: PCT/US2021/048257

§ 371 Date: Feb. 28, 2023

Related U.S. Application Data
(60) Provisional application No. 63/078,302, filed on Sep. 14, 2020.

(51) Int. Cl. C23C 16/44; H01L 21/687

(52) U.S. Cl. CPC C23C 16/4401; H01L 21/68771

(57) ABSTRACT

In some examples, a rib cover is provided for a multi-station processing module having a rib disposed between adjacent processing chambers. An example rib cover comprises a first portion for supporting the rib cover on the rib, a first side shield to cover a first wall of the rib when the rib cover is fitted thereto, and at least one spacer to hold an inner surface of the rib cover away from the covered rib.

### CLAIM OF PRIORITY

This application claims the benefit of priority to U.S. Patent Application Ser. No. 63/078,302, filed on Sep. 14, 2020, which is incorporated by reference herein in its entirety.

### FIELD

The present disclosure relates generally to a rib cover for a multi-station substrate processing module, and more particularly to a rib cover for a quad station processing module (QS).

### BACKGROUND

In some substrate processes in the vacuum chambers of a QSM, a high defect count may be observed along edges of the substrate closest to the chamber ribs which extend between adjacent processing chambers. Deposition on the surface of a chamber rib can be redistributed to the surface of the substrate, such as a wafer, through peeling or flaking of the deposited material. This fallout can be observed as an on-wafer defect or particle distribution.

Currently, to remove such debris, an in situ chamber clean is performed after processing a certain number of wafer batches. In some instances, the number of wafer batches between cleans is too small to allow compliance with throughput targets of wafers per hour. Extending the time between chamber cleans may increase wafer throughput.

The background description provided here is to generally present the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### BRIEF SUMMARY

In some examples, a rib cover for a multi-station processing module is provided. The processing module has a rib disposed between adjacent processing chambers of the processing module. An example rib cover comprises a first portion configured to support the rib cover on a rib of the multi-station processing module; a first side shield configured to cover a first wall of the rib; and at least one spacer configured to hold a first surface of the rib cover away from the rib.

In some examples, the rib cover further comprises a second side shield to cover a second wall of the rib when the rib cover is fitted thereto.

In some examples, the upper portion and the first and second side shields of the rib cover define a channel for the rib cover.

In some examples, the channel includes a flared mouth.

In some examples, an engagement of the flared mouth with the rib prevents radial movement of the rib cover with respect to the processing module.

In some examples, the channel is configured to support or old the rib cover on the rib under gravity alone.

In some examples, the at least one spacer is located in the channel, the channel configured to support or hold the rib cover on the rib by a sliding fit or by a frictional engagement between the at least one spacer and the rib.

In some examples, the at least one spacer is configured to minimize thermal contact between the rib cover and the rib.

In some examples, a separation distance between the rib cover and the rib is in a range of 0.05 to 0.50 inches (approximately 1.27 to 12.7 mm).

In some examples, a sectional thickness of the rib cover or the channel is in a range of 0.25 to 0.70 inches (approximately 6.35 to 17.78 mm).

In some examples, at least a second portion of the rib cover includes a ceramic material.

In some examples, a multi-station processing module has a rib disposed between adjacent processing chambers of the processing module.

An example processing module comprises a rib cover. An example rib cover comprises a first portion configured to support the rib cover on a rib of the multi-station processing module; a first side shield configured to cover a first wall of the rib; and at least one spacer configured to hold a first surface of the rib cover away from the rib.

In some examples, the rib cover further comprises a second side shield to cover a second wall of the rib when the rib cover is fitted thereto.

In some examples, the first portion and the first and second side shields of the rib cover define a channel for the rib cover.

In some examples, the channel includes a flared mouth.

In some examples, an engagement of the flared mouth with the rib prevents radial movement of the rib cover with respect to the processing module.

In some examples, the channel is configured to support or hold the rib cover on the rib under gravity alone.

In some examples, the at least one spacer is located in the channel, the channel configured to support or hold the rib cover on the rib by a sliding fit or by a frictional engagement between the at least one spacer and the rib.

In some examples, the at least one spacer is configured to minimize thermal contact between the rib cover and the rib.

In some examples, a separation distance between the rib cover and the rib is in a range of 0.05 to 0.50 inches (approximately 1.27 to 12.7 mm).

In some examples, a sectional thickness of the rib cover or the channel is in a range of 0.25 to 0.70 inches (approximately 6.35 to 17.78 mm).

In some examples, at least a second portion of the rib cover includes a ceramic material.

In some examples, a method of operating a multi-station processing module is provided. An example processing module has a rib disposed between adjacent processing chambers of the processing module. An example method comprises providing a rib cover for the rib, the rib cover comprising a first portion configured to support the rib cover on a rib of the multi-station processing module, the rib disposed between adjacent processing chambers of the multi-station processing module; a first side shield to cover a portion of a wall of a first processing chamber of the adjacent processing chambers of the multi-station processing module; and at least one spacer configured to hold a first surface of the first portion, or a surface of the first side shield, away from a surface of the wall of the first processing chamber of the processing module; and fitting the rib cover to the rib.

In some examples, the method further comprises removing a residual deposition from the rib cover between processing cycles of the processing module.

### BRIEF DESCRIPTION OF THE SEVERAL VIEWS OF THE DRAWINGS

Some embodiments are illustrated by way of example and not limitation in the views of the accompanying drawing:

FIGS. 1-5 show schematic views of substrate processing tools, according to some example embodiments.

FIG. 6 shows a schematic diagram of an example processing chamber within which examples of the present disclosure may be employed.

FIG. 7 shows a pictorial view of an open QSM, according to an example embodiment.

FIGS. 8A-8B show pictorial top and underside views of a rib cover, according to an example embodiment.

FIG. 9 shows a schematic view of a QSM illustrating example on-wafer particle distributions, according to example embodiments.

FIG. 10 shows operations in an example method of operating a multi-station processing module, according to some examples.

### DETAILED DESCRIPTION

The description that follows includes systems, methods, techniques, instruction sequences, and computing machine program products that embody illustrative embodiments of the present disclosure. In the following description, for purposes of explanation, numerous specific details are outlined to provide a thorough understanding of example embodiments. It will be evident, however, to one skilled in the art that the present disclosure may be practiced without these specific details.

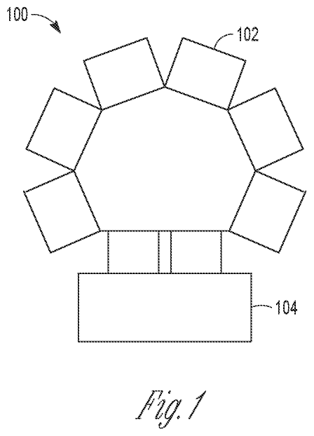

Referring now to FIG. 1, a top-down view of an example substrate processing tool 100 is shown. The substrate processing tool 100 includes a plurality of process modules 102. In some examples, each of the process modules 102 may be configured to perform one or more respective processes on a substrate. Substrates to he processed arc loaded into the substrate processing tool 100 via ports of a loading station of an EFEM 104 (equipment front end module) and then transferred into one or more of the process modules 102. For example, a substrate may be loaded into each of the process modules 102 in succession.

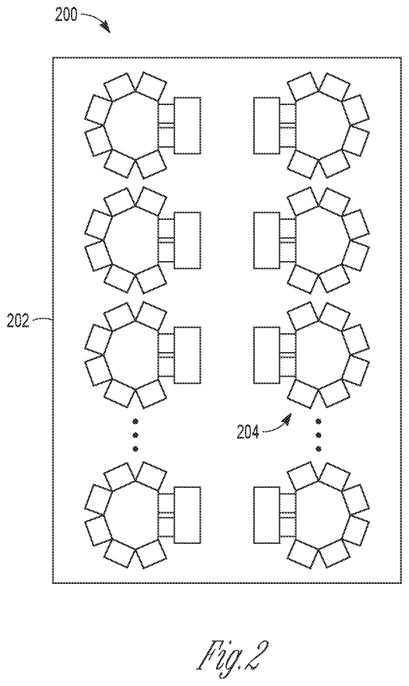

Referring now to FIG. 2, an example arrangement 200 of a fabrication room 202. including a plurality of substrate processing tools 204 is shown.

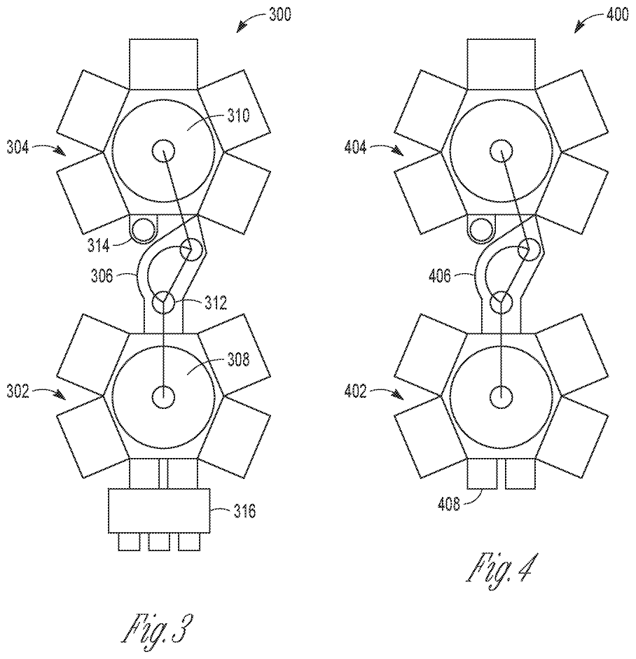

FIG. 3 shows a first example configuration 300 including a first substrate processing tool 302 and a second substrate processing tool 304. The first substrate processing tool 302 and the second substrate processing tool 304 are arranged sequentially and are connected by a transfer stage 306, which is under vacuum. As shown, the transfer stage 306 includes a pivoting transfer mechanism configured to transfer substrates between a VTM 308 (vacuum transfer module) of the first substrate processing tool 302 and a VTM 310 of the second substrate processing tool 304. However, in other examples, the transfer stage 306 may include other suitable transfer mechanisms, such as a linear transfer mechanism. In some examples, a first robot (not shown) of the VTM 308 may place a substrate on a support 312 arranged in a first position; the support 312 is pivoted to a second position, and a second robot (not shown) of the VTM 310 retrieves the substrate from the support 312 in the second position. In some examples, the second substrate processing tool 304 may include a storage buffer 314 configured to store one or more substrates between processing stages.

The transfer mechanism may also be stacked to provide two or more transfer systems between the first substrate processing tool 302 and the second substrate processing tool 304. Transfer stage 306 may also have multiple slots to transport or buffer multiple substrates at one time.

In the example configuration 300, the first substrate processing tool 302 and the second substrate processing tool 304 are configured to share a single EFEM 316 (equipment front end module).

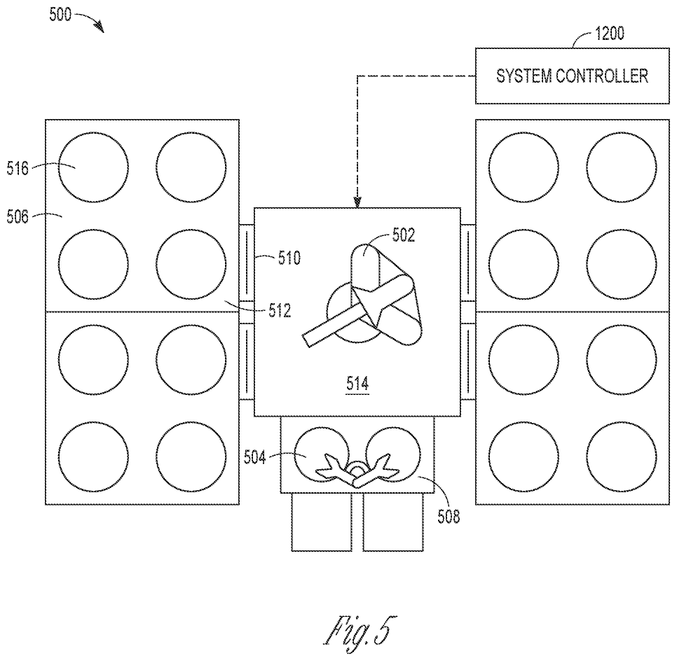

FIG. 4 shows a second example configuration 400 including a first substrate processing tool 402 and a second substrate processing tool 404 arranged sequentially and connected by a transfer stage 406. The example configuration 400 is similar to the example configuration 300 of FIG. 3 except that in the example configuration 400, the EFEM is eliminated. Accordingly, substrates may be loaded into the first substrate processing tool 402 directly via airlock loading stations 408 (e.g., using a storage or transport carrier such as a vacuum wafer carrier, front opening unified pod (FOUP), an atmospheric (ATM) robot, etc., or other suitable mechanisms).

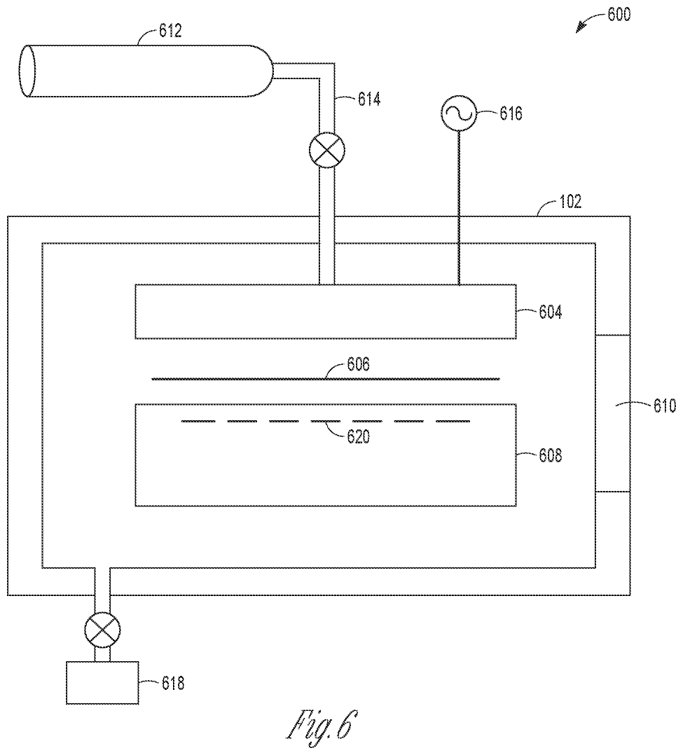

The apparatus, systems, and methods of the present disclosure may be applied to multi-station processing modules, more particularly to quad station processing modules (QSM's). In some examples, as shown in FIG. 5, a substrate processing tool 500 is shown. The substrate processing tool 500 includes four QSM's 506. Each of the QSM's 506 includes four stations 516 (hence quad station module). Each station 516 may include a processing chamber or vacuum chamber. The substrate processing tool 500 includes transfer robot 502 and transfer robot 504, referred to collectively as transfer robots 502/504. The substrate processing tool 500 is shown without mechanical indexers for example purposes. In other examples, respective QSM's 506 of the substrate processing tool 500 may include mechanical indexers to transfer substrates (for example, wafers) from station to station in a given QSM 506. An indexer may include a carrier or exclusion ring.

A VTM 514 and an EFEM 508 may each include one of the transfer robots 502/504. The transfer robots 502/504 may have the same or different configurations. In some examples, the transfer robot 502 is shown having two arms, each having two vertically stacked end effectors. The transfer robot 504 of the VTM 514 selectively transfers substrates to and from the EFEM 508 and between the QSM's 506. The transfer robot 504 of the EFEM 508 transfers substrates into and out of the EFEM 508. In some examples, the transfer robot 504 may have two wins, each arm having a single end effector or two vertically stacked end effectors. A system controller 1200 may control various operations of the illustrated substrate processing tool 500 and its components including, but not limited to, operation of the robots 502/504, and rotation of the respective indexers of the QSM's 506.

The VTM 514 is configured to interface with, for example, all four of the QSM's 506 each having a single load station accessible via a respective slot 510. In this example, sides 512 of the VTM 514 are not angled (i.e., the sides 512 are substantially straight or planar). In this manner, two of the QSM's 506, each having a single load station, may be coupled to each of the sides 512 of the VTM 514. Accordingly, the EFEM 508 may be arranged at least partially between two of the QSM's 506 to reduce the footprint of the substrate processing tool 500.

With reference now to FIG. 6, an example, simplified arrangement 600 of a plasma-based processing chamber provided at each of the stations 516 is shown. The present subject matter may be used in a variety of semiconductor manufacturing and wafer processing operations, but in the illustrated example, the plasma-based processing chamber is described in the context of plasma-enhanced or radical-enhanced Chemical Vapor Deposition (CVD) or Atomic Layer Deposition (ALD) operations. The skilled artisan will recognize that other types of ALD processing techniques are known (e.g., thermal-based ALD operations) and may incorporate a non-plasma-based processing chamber. An ALD tool is a specialized type of CVD processing system in which ALD reactions occur between two or more chemical species. The two or more chemical species are referred to as precursor gases and are used to form a thin film deposition of a material on a substrate, such as a silicon wafer as used in the semiconductor industry. The precursor gases are sequentially introduced into an ALD processing chamber and react with a surface of the substrate to form a deposition layer. Generally, the substrate repeatedly interacts with the precursors to deposit slowly an increasingly thick layer of one or more material films on the substrate. In certain applications, multiple precursor gases may be used to form various types of film or films during a substrate manufacturing process.

FIG. 6 is shown to include a plasma-based processing chamber 102 in which a showerhead 604 (which may be a showerhead electrode) and a substrate-support assembly 608 or pedestal are disposed. Typically, the substrate-support assembly 608 provides a substantially isothermal surface and may serve as both a heating element and a heat sink for a substrate 606. The substrate-support assembly 608 may comprise an Electrostatic Chuck (ESC) in which heating elements are included to aid in processing the substrate 606, as described above. The substrate 606 may include a wafer comprising, for example, elemental-semiconductor materials (e.g., silicon (Si) or germanium (Ge)) or compound-semiconductor materials (e.g., silicon germanium (SiGe) or gallium arsenide (GaAs)). Additionally, other substrates include, for example, dielectric materials such as quartz, sapphire, semi-crystalline polymers, or other non-metallic and non-semiconductor materials.

In operation, the substrate 606 is loaded through a loading port 610 onto the substrate-support assembly 608. An exclusion ring may load the wafer onto the substrate-support assembly 608. Other loading arrangements are possible. A gas line 614 can supply one or more process gases (e.g., precursor gases) to the showerhead 604. In turn, showerhead 604 delivers the one or more process gases into the plasma-based processing chamber 602. A gas source 612 (e.g., one or more precursor gas ampules) to supply the one or more process gases is coupled to the gas line 614. In some examples, an RF (radio frequency) power source 616 is coupled to the showerhead 604. In other examples, a power source is coupled to the substrate-support assembly 608 or ESC.

Before entry into showerhead 604 and downstream of the gas line 614, a point-of-use (POU) and manifold combination (not shown) controls the entry of the one or more process gases into the plasma-based processing chamber 602. In the case of a plasma-based processing chamber 602 used to deposit thin films in a plasma-enhanced ALD operation, precursor gases may be mixed in the showerhead 604.

In operation, the plasma-based processing chamber 602 is evacuated by a vacuum pump 618. RF power is capacitively coupled between the showerhead 604 and a lower electrode 620 contained within or on the substrate-support assembly 608. The substrate-support assembly 608 is typically supplied with two or more RF frequencies. For example, in various embodiments, the RF frequencies may be selected from at least one frequency at about 1 MHz, 2 MHz, 13.56 MHz, 27 MHz, 60 MHz, and other frequencies as desired. A coil designed to block or partially block a particular RF frequency can be designed as needed. Therefore, particular frequencies discussed herein are provided merely for ease of understanding. The RF power is used to energize the one or more process gases into a plasma in the space between the substrate 606 and the showerhead 604. The plasma can assist in depositing various layers (not shown) on the substrate 606. In other applications, the plasma can be used to etch device features into the various layers on the substrate 606. RF power is coupled through at least the substrate-support assembly 608. The substrate-support assembly 608 may have heaters (not shown in FIG. 6) incorporated therein. The detailed design of the plasma-based processing chamber 602 may vary.

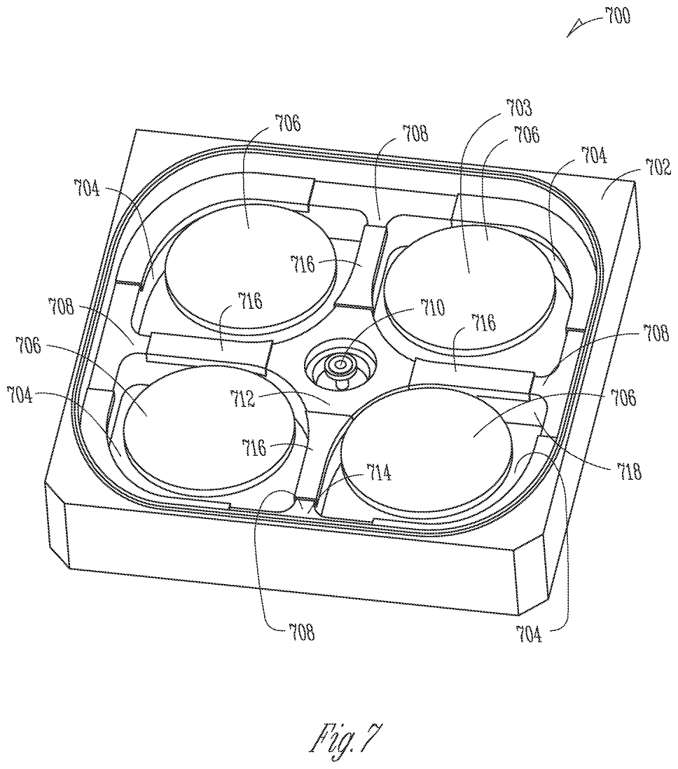

FIG. 7 is a pictorial view 700 of an open multi-station processing module, in this case, a QSM 702. One processing station 703 in each quadrant of the QSM 702 may be seen. Other numbers of stations are possible. Each station 703 includes a substrate processing chamber 704. For clarity, components such as substrate transfer paddles and a top plate for forming a vacuum seal in the processing chamber 704 are not shown. Each processing chamber 704 is shown to include a substrate-support assembly 706 (substrate not shown) and a paddle spindle 710.

An aluminum chamber rib 708 is disposed between each of the processing chambers 704. In this example, the QSM 702 includes four chamber ribs 708. Other numbers of ribs 708 are possible. Each chamber rib 708 extends from an inner end 712 thereof to an outer end 714 thereof in a radial direction away from the paddle spindle 710. A rib cover 716, described more fully below, covers each rib 708.

As mentioned above, in some substrate processes performed in the processing chambers of the QSM 702, a high defect count may be observed along edges of a processed substrate located closest to a respective chamber rib 708. Material deposited on the surface of a chamber rib 708 is liable to be redistributed to the surface of the processed substrate through peeling or flaking of the deposited material. In some examples, the provision of a rib cover 716 addresses this problem. A ceramic rib cover 716 fitted over a rib 708 may prevent or reduce the deposition of material onto the underlying surface of the rib 708. Alternatively, deposition that may form on the rib cover 716 during substrate processing may be cleaned off after a number of cycles to prevent (or minimize) the deposited material from falling onto the substrate. In some examples, by dint of its ceramic surface properties, the rate of deposition of material onto the rib cover 716 is lower than would occur on the underlying aluminum surface of the rib 708, and the deposited material may be more tenacious in adhering to the ceramic surface of the rib cover 716 than the underlying aluminum surface of the rib 708.

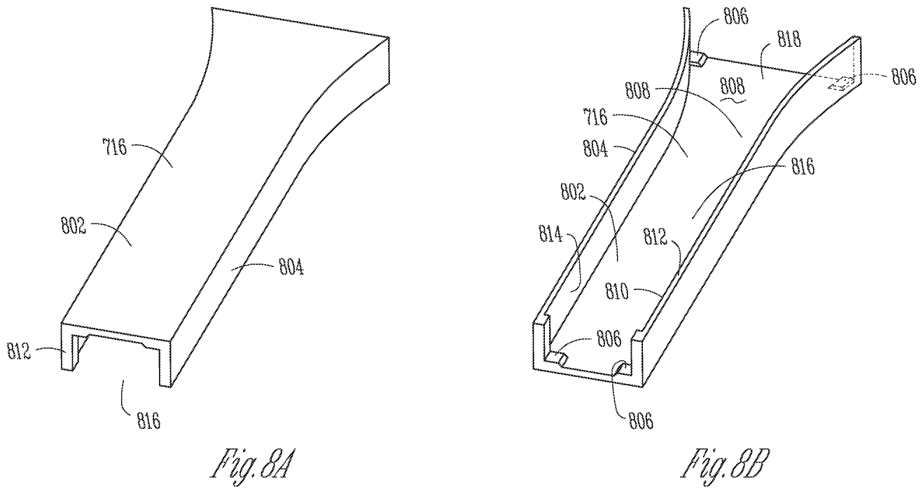

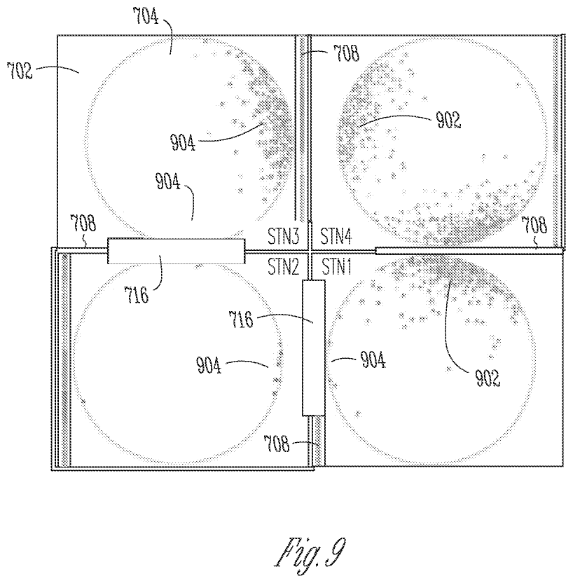

FIGS. 8A-8B show top and underside pictorial views of an example rib cover 716. The rib cover 716 may be installed in a multi-station processing module, for example, a QSM 702, to cover a chamber rib 708 disposed between two adjacent processing chambers 704 of the QSM 702.

The rib cover 716 comprises a first (or support) portion 802 (also referred to as upper portion) for supporting the rib cover 716 on the rib 708. The rib cover 716 further comprises two side shields, a first side shield 804 and a second side shield 812. When installed, each side shield 804 and 812 covers a portion of a rib 708 between adjacent processing chambers 704, for example, the wall 718 in FIG. 7. In most examples, a covered portion of a wall 718 may not necessarily be part of a rib 708. Other wall or rib covering arrangements are possible. A set of four rib covers 716 may each cover a respective rib 708 of a QSM 702 in the manner shown in FIG. 7.

With reference in particular to FIG. 8B, the example rib cover 716 includes at least one spacer, in this case, four spacers 806. Each spacer 806 holds a surface 808 (e.g., inner surface) of the first portion 802, or surfaces 810 and 814 (e.g., inner surfaces) of the respective first and second side shields 804 and 812, away from a surface of the wall of the first processing chamber 704 or a wall of the rib 708.

In some examples, the first portion 802 and the first and second side shields 804 and 812 of the rib cover 716 define an open channel 816 for the rib cover 716. The volume of the channel 816 defined by the first portion 802 and side shields 804 and 812 is configured to accommodate a first portion (also referred to as upper portion) of a rib 708 when fitted thereto, as shown for example in FIG. 7. In some examples, channel 816 includes a flared, open mouth 818. Engagement of the flared mouth 818 with a diverging, radially inner end of a rib 708 (for example as shown in FIG. 7) prevents further inward radial movement of the rib cover 716 with respect to the rib 708 and the processing chambers 704 of the QSM 702.

In some examples, one or more of the spacers 806 is located in channel 816. In some examples, channel 816 is sized and configured to support or hold the rib cover 716 on a rib 708 under gravity alone. In this instance, one or more of the spacers 806 may engage the rib 708 in a loose or sliding fit. In some examples, channel 816 is configured to support or hold the rib cover 716 on a rib 708 by frictional engagement between one or more of the spacers 806 and the rib 708 or a wall of a processing chamber 704.

The occurrence of certain undesired defect counts during substrate processing has been mentioned further above. In some examples, a QSM 702 running ashable hard mask (AHM) processes observes high defect counts along the edge of the wafer closest to an aluminum chamber rib 708 within a processing or vacuum chamber. Deposition on the surface of the rib 708 is believed to be redistributed onto the processed substrate (for example, a wafer) through peeling or flaking. To assist in preventing this problem, some example spacers are provided as “minimal contact” spacers 806, or mini pads. In such examples, a mini pad/spacer 806 is configured to reduce or minimize physical and/or thermal contact between the rib cover 716 and the rib 708, or processing chamber wall, to which the rib cover 716 is fitted. The rib cover 716 is held away from the heat sink of the aluminum processing chamber 704. This reduced physical and/or thermal contact allows the rib cover 716 to heat up under parasitic plasma exposure and thereby prevent or reduce condensation of the AHM film and eliminate or mitigate this phenomenon as a defect source.

In some examples, a mini pad/spacer 806 holds the surface of the channel 816 away from a wall of the rib 708 or processing chamber 704 by a separation distance. The separation distance may be in the range of 0.05 to 0.50 inches (approximately 1.27 to 12.7 mm). A separation distance may be selected within this range to optimize a sensitivity quality, for example, to minimize potential electrical arcing across the air space between the rib cover 716 and rib 708. A separation distance may also he selected to minimize the accumulation of debris or processing artifacts underneath the rib cover 716.

In some examples, the rib cover 716 is configured to be sufficiently robust to withstand rough handling and multiple, repeated fitments into a processing chamber 704. Some examples are further configured to survive repeated exposure to harsh substrate processing conditions. To this end, a sectional thickness of a portion of the rib cover 716 or the channel 816, for example, a sectional thickness of a side shield 804 or 812, may be provided in the range of 0.25 to 0.70 inches (approximately 6.35 to 17.78 mm). In some examples, at least a portion of the rib cover includes a ceramic material, such as alumina. Other ceramics may be acceptable.

Typically, the aluminum chambers of a QSM 702 are water-cooled, but the selection of an appropriate ceramic material, in conjunction with the placement of minimal contact spacers (such as the mini pads/spacers 806) in channel 816, allows the ceramic material of the rib cover 716 to absorb the majority of the heat emanating from the parasitic plasma because the captured heat is not conducted away into the aluminum processing chamber 704. This in turn can prevent film condensation and a more tenacious adherence of deposited material to the rib cover 716 and not a substrate being processed in chamber 704.

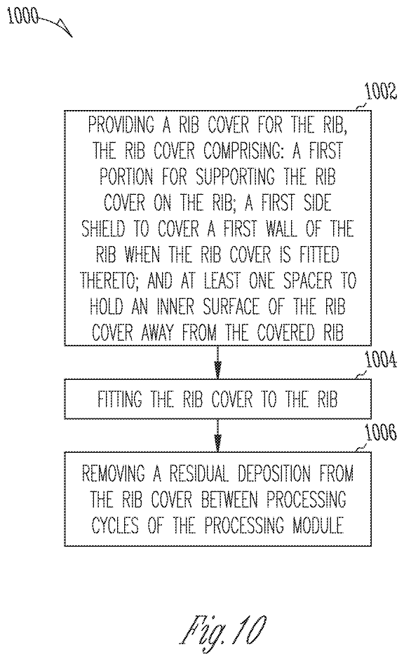

Concerning FIG. 9, testing was carried out on a QSM 702 which included four stations, labeled STN 1-4 in the schematic view. Two of four ribs 708 of the QSM 702 were fitted with rib covers 716, as shown, namely between STN1 and STN2, and between STN2 and STN 3. After testing, the distribution of on-wafer particles was identified for each station. Heavy particle distributions 902 may be observed for substrate regions adjacent to an uncovered rib 708. Much lighter particle distributions 904 may be observed for substrate regions adjacent to a covered rib 708 protected by a rib cover 716. On-wafer defect performance is thereby significantly improved.

Provision of a rib cover 716 may be considered in some examples to be a passive solution and therefore low cost in nature. A rib cover 716 can be readily installed on new tools as well as retrofitted to tools in the field without requiring the removal of existing hardware. In some examples, the provision of a rib cover 716 does not impact existing process recipes; in other words, it is recipe transparent.

Some examples of this disclosure include method embodiments. With reference to FIG. 10, example operations are provided for a method 1000 of operating a multi-station processing module having a rib disposed between adjacent chambers of the processing module. The method 1000 comprises: at operation 1002, providing a rib cover for the rib, the rib cover comprising: a first portion (also referred to as upper portion) for supporting the rib cover on the a first side shield to cover a first wall of the rib when the rib cover is fitted thereto; and at least one spacer to hold a first surface of the rib cover away from the covered rib; and, at operation 1004, fitting the rib cover to the rib. Method 1000 may further comprise, at operation 1006, removing a residual deposition from the rib cover between processing cycles of the processing module.

Although examples have been described with reference to specific example embodiments or methods, it will be evident that various modifications and changes may be made to these embodiments without departing from the broader scope of the embodiments. Accordingly, the specification and drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may he utilized and derived therefrom, such that structural and logical substitutions and changes may be made without departing from the scope of this disclosure. This detailed description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is disclosed. Thus, although specific embodiments have been illustrated and described herein, it should be appreciated that any arrangement calculated to achieve the same purpose may be substituted for the specific embodiments shown. This disclosure is intended to cover any adaptations or variations of various embodiments. Combinations of the above embodiments, and other embodiments riot specifically described herein, will be apparent to those of skill in the art upon reviewing the above description.

Although examples have been described with reference to specific example embodiments or methods, it will be evident that various modifications and changes may be made to these embodiments without departing from the broader scope of the embodiments. Accordingly, the specification and drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This detailed description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is disclosed. Thus, although specific embodiments have been illustrated and described herein, it should be appreciated that any arrangement calculated to achieve the same purpose may be substituted for the specific embodiments shown. This disclosure is intended to cover any adaptations or variations of various embodiments. Combinations of the above embodiments, and other embodiments not specifically described herein, will be apparent to those of skill in the art upon reviewing the above description.

What is claimed is:

1. A rib cover for a multi-station processing module, the rib cover comprising:
a first portion configured to support the rib cover on a rib of the multi-station processing module, the rib disposed between adjacent processing chambers of the multi-station processing module;
a first side shield configured to cover a first wall of the rib; and
at least one spacer configured to hold a first surface of the rib cover away from the rib.

2. The rib cover of claim 1, further comprising a second side shield to cover a second wall of the rib when the rib cover is fitted thereto.

3. The rib cover of claim 2, wherein the first portion and the first and second side shields of the rib cover define a channel for the rib cover.

4. The rib cover of claim 3, wherein the channel includes a flared mouth.

5. The rib cover of claim 4, wherein engagement of the flared mouth with the rib prevents radial movement of the rib cover with respect to the processing module.

6. The rib cover of claim 3, wherein the channel is configured to support or hold the rib cover on the rib under gravity alone.

7. The rib cover of claim 3, wherein the at least one spacer is located in the channel, the channel configured to support or hold the rib cover on the rib by a sliding fit or by a frictional engagement between the at least one spacer and the rib.

8. The rib cover of claim 3, wherein the at least one spacer is configured to minimize thermal contact between the rib cover and the rib.

9. The rib cover of claim 8, wherein a separation distance between the rib cover and the rib is in a range of 0.05 to 0.50 inches (approximately 1.27 to 12.7 mm).

10. The rib cover of claim 3, wherein a sectional thickness of the rib cover or the channel is in a range of 0.25 to 0.70 inches (approximately 6.35 to 17.78 mm).

11. The rib cover of claim 1, wherein at least a second portion of the rib cover includes a ceramic material.

12. A multi-station processing module comprising:
a rib cover comprising:
a first portion configured to support the rib cover on a rib of the multi-station processing module, the rib disposed between adjacent processing chambers of the multi-station processing module;
a first side shield configured to cover a first wall of the rib; and
at least one spacer configured to hold a first surface of the rib cover away from the rib.

13. The multi-station processing module of claim 12, wherein the rib cover further comprises a second side shield to cover a second wall of the rib when the rib cover is fitted thereto.

14. The multi-station processing module of claim 13, wherein the first portion and the first and second side shields of the rib cover define a channel for the rib cover.

15. The multi-station processing module of claim 14, wherein the channel includes a flared mouth.

16. The multi-station processing module of claim 15, wherein engagement of the flared mouth with the rib prevents radial movement of the rib cover with respect to the processing module.

17. The multi-station processing module of claim 14, wherein the channel is configured to support or hold the rib cover on the rib under gravity alone.

18. The multi-station processing module of claim 14, wherein the at least one spacer is located in the channel, the channel configured to support or hold the rib cover on the rib by a sliding fit or by a frictional engagement between the at least one spacer and the rib.

19. The multi-station processing module of claim 14, wherein the at least one spacer is configured to minimize thermal contact between the rib cover and the rib.

20. The multi-station processing module of claim 19, wherein a separation distance between the rib cover and the rib is in a range of 0.05 to 0.50 inches (approximately 1.27 to 12.7 mm).

21. The multi-station processing module of claim 14, wherein a sectional thickness of the rib cover or the channel is in a range of 0.25 to 0.70 inches (approximately 6.35 to 17.78 mm).

22. The multi-station processing module of claim 12, wherein at least a second portion of the rib cover includes a ceramic material.

23. A method of operating a multi-station processing module, the method comprising:
providing a rib cover for the rib, the rib cover comprising:
a first portion configured to support the rib cover on a rib of the multi-station processing module, the rib disposed between adjacent processing chambers of the multi-station processing module:
a first side shield to cover a portion of a wall of a first processing chamber of the adjacent processing chambers of the multi-station processing module; and
at least one spacer configured to hold a first surface of the first portion, or a surface of the first side shield, away from a surface of the wall of the first processing chamber of the processing module; and
fitting the rib cover to the rib.

24. The method of claim 23, further comprising removing a residual deposition from the rib cover between processing cycles of the processing module.
